(19) United States
(12) Patent Application Publication
(10) Pub. No.: US 2011/0187393 A1
(43) Pub. Date: Aug. 4, 2011

(54) MOISTURE DETECTION SENSORS FOR BUILDING STRUCTURES

(76) Inventors: David E. Vokey, Sidney (CA); Hani Nassar, Hickory, NC (US); Jody Aaron Wells, Victoria (CA); James Gary Coburn, Victoria (CA)

(21) Appl. No.: 12/854,582

(22) Filed: Aug. 11, 2010

Related U.S. Application Data
(62) Division of application No. 10/534,882, filed on Feb. 1, 2007.
(60) Provisional application No. 60/488,090, filed on Jul. 18, 2003.

(30) Foreign Application Priority Data
Jul. 14, 2004 (CA) 2513387

(51) Int. Cl. G01R 27/08

(52) U.S. Cl. 324/694

(57) ABSTRACT

A moisture detection sensor self-adhesive tape is used in a building structure to detect moisture penetration and includes a substrate of dielectric, hydrophobic material. Two elongate, parallel, conductors are secured to the top surface of the substrate and a protective layer of non-hygroscopic, water pervious material secured to the to the top surface of the substrate, over the conductors. A pressure sensitive mounting adhesive is placed on a bottom surface of the substrate and covered with a release sheet. The sensor may include moisture probes adapted to penetrate the protective layer, the respective conductors and the substrate and to extend into a building component to which the substrate has been adhered. The preferred moisture probe is a U-shaped metal staple configured to be driven in by a conventional power stapler.

This application is a divisional application of application Ser. No. 10/534,882 filed Feb. 1, 2007 which is a 371 National Phase application of PCT/US04/22609 filed Jul. 14, 2004.

This application claims the benefit under 35 USC 119(e) of Provisional Application 60/488,090 filed Jul. 18, 2003.

The present invention relates to a tape and method for use in the detection of water penetration into residential and commercial buildings.

### BACKGROUND OF THE INVENTION

Water intrusion into buildings is a massive and growing problem. Leaking buildings cost homeowners, commercial property owners and property insurers hundreds of millions of dollars every year. Even the smallest leaks that channel water into building walls can cause expensive problems. Structural damage to plywood sheathing and stud walls due to wood rot has been commonplace for decades. Black mold or toxic mold that grows in the wet walls is known to cause severe physical problems for occupants as well as severe fiscal problems for builders and insurance companies.

Early detection and location of building envelope penetration will allow the builder or owner to identify developing problems and carry out minor repairs. Homeowners, builders, and insurance companies can avoid high costs resulting from extensive structural damage, health problems, insurance claims and potential lawsuits.

Several water detection sensors are commercially available. Moisture detection tapes, spot sensors and cables of various designs are known. The available sensors are designed for use on floors and plumbing fixtures, or to be wrapped around pipes. One form of detection tape, with flat, exposed conductors is designed for open use and is not suitable for direct placement within a building structure where metallic building elements could cause a short across the exposed sensing elements. A tape of this type is disclosed in U.S. Pat. No. 6,175,310. None of the currently available sensors is suited for placement within a building structure next to the protective moisture barrier that is often referred to as the building envelope.

An even greater problem that the prior art does not address is the potential for wood elements to absorb moisture to the point of saturation without being detected. Plywood or OSB sheathing and lumber studs, joists, beams and rafters can easily absorb a slow leak of water through the building envelope. The ingress of water can be at a sufficiently low rate that the hygroscopic properties of wood allow total absorption without a detectable amount on the surface to dampen and create a conductive path between the sensing conductors. The present invention addresses these shortcomings and provides a novel and effective moisture detection system.

### SUMMARY OF THE INVENTION

According to one aspect of the present invention there is provided a moisture detection sensor comprising:

a substrate of dielectric, hydrophobic material;

two elongate, parallel, conductors secured to a top surface of the substrate;

a protective layer of non-hygroscopic, water pervious material secured to the to surface of the substrate and extending over the conductors; and

a mounting adhesive on a bottom surface of the substrate.

The preferred sensor is an elongate tape suitable for placement within a building structure, adjacent the building envelope. The moisture detection tape may be placed in areas prone to water ingress to detect the first trace of moisture penetration. The detection tape conductors are connected to the input leads of a remote sensor unit which, when triggered by the detection tape, transmits coded alarm signals.

The tape is of laminated construction with the preferred configuration having a substrate of rugged, high-dielectric strength and two flat copper conductors adhered to the dielectric substrate. The high-dielectric strength substrate provides mechanical strength and electrical insulation from the surface it is applied to. The substrate is coated with a pressure sensitive mounting adhesive that provides good adhesion to standard building materials such as wood, wood laminates, concrete, steel, galvanized steel, PVC, ceramic, etc. The adhesive backing is desirably non-water soluble and selected to provide good adhesion characteristics over the anticipated application temperature range, e.g. −10° C. to +50° C. The adhesive backing is protected prior to installation by a peel-off release layer. The protective non-hygroscopic dielectric layer over the conductors provides mechanical and insulating properties such that contact with metal surfaces does not cause a short circuit across the conductors while allowing water to penetrate to the conductor surfaces and bridge the gap between the conductors.

The conductors are preferably flat metal strips no less than 6.5 mm wide and spaced apart by a distance no less than 13 mm, preferably 13.6 mm. The width and spacing of the flat copper conductors are of importance in the preferred design. The conductor should be of sufficient width that a nail or screw of up to 4.8 mm in diameter, such is commonly used in construction, will not cut the conductor in two if inadvertently driven through the tape. The conductor spacing should be such that a misplaced construction staple of up to 12.7 mm wide cannot bridge the space between the conductors and cause a short circuit between the conductors.

A further moisture detection component may be incorporated to detect and measure moisture that has been absorbed directly into an underlying building component, for example an absorbent wood component. This can occur without wetting the detection tape surface and would go undetected. To deal with this, the sensor includes at least two moisture probes adapted to penetrate the protective layer, the respective conductors and the substrate and to extend into a building component to which the substrate has been adhered, each probe being a conductive element of corrosion resistant material.

According to another aspect of the present invention there is provided a moisture detection sensor comprising:

an elongate tape;

two elongate, parallel, conductors secured to a top surface of the tape;

at least two moisture probes adapted to penetrate the tape and the respective conductors and to extend into a building component to which the tape has been attached, each probe being a conductive element of corrosion resistant material.

In use, a pair of the, non-corroding probes, appropriately calibrated, are inserted though the conductors into an structure of absorbent material, for example wood. This is especially useful at critical points, for example, the area below a window sill, the sheathing just above a floor plate, and the floor joists below an exterior door. The probes are intended to make intimate electrical contact with the detection conductors. The detection conductors then serve as conductors whereby electronic sensors connected to the end of the detection tape are electrically connected to the moisture probes.

According to a further aspect of the present invention, there is provided a method of detecting moisture in an absorbent material, the method comprising:

providing two conductors on or adjacent a surface of the material; and

penetrating each conductor and the absorbent material with a conductive probe;

applying a voltage across the two conductors; and

monitoring currents passing between the conductors.

In a building structure, the absorbent material will normally be a wood component that may be wet internally, although there is insufficient moisture on the surface to trigger a surface mounted sensor, for example the tape alone. The internal moisture would, in the absence of the probes, go undetected, and might result in rotting of the wood structure.

### BRIEF DESCRIPTION OF THE DRAWINGS

In the accompanying drawings, which illustrate exemplary embodiments of the present invention:

FIG. 1 is a top view of the flat conductors and substrate of a detection tape;

FIG. 2 is an exploded sectional view along line II-II of FIG. 1 showing the various layers of the detection tape;

FIG. 3 is a graph of probe to probe resistance versus moisture content;

FIG. 4 is an isometric view of a moisture probe;

FIG. 5 is an end view of the probe; and

FIG. 6 illustrates the connection of the detection tape to a sensor unit.

### DETAILED DESCRIPTION

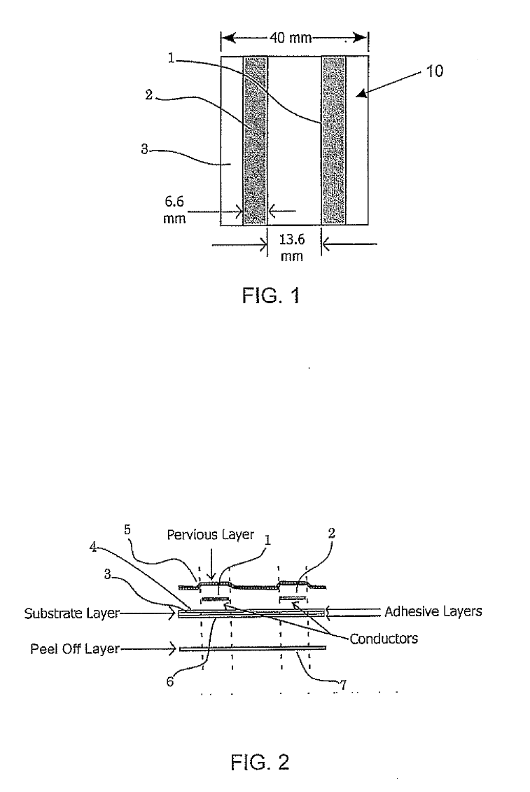

Referring to the accompanying drawings, and particularly FIGS. 1 and 2, there is illustrated a moisture detection tape 100. The tape is constructed by applying a non-water soluble adhesive 4 to a 40 mm wide×0.1 mm thick polyvinyl chloride substrate 3. Two 0.1 mm thick×6.6 mm wide soft bare copper strips 1, 2 are laid down on the adhesive coated substrate with a 13.6 mm edge-to-edge separation. A non-hygroscopic, non-woven, water pervious layer 5 is applied over the polyvinyl substrate 3 and the copper conductors 1, 2. A non-water soluble adhesive layer 6 that will adhere to common building materials such as wood, steel, concrete, etc. is applied to the underside of the polyvinyl substrate 3. A 40 mm wide×0.1 mm thick peel off release layer 7 is applied over the underside adhesive layer 6.

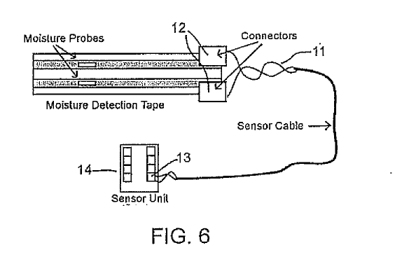

Referring to FIG. 6, when the tape is installed on a moisture absorbent building element, for example wood, moisture probes 9, 10 are inserted through the detection tape conductors at critical point-locations. The probes are constructed of stainless or copper-clad steel. Each of the probes 9 and 10 is of a dual prong design as illustrated in FIGS. 4 and 5 and is in the form of a conventional staple with a crown 90 and two legs or pins 91 as is well known. Such a staple can be inserted with a standard construction-stapling tool. Thus, as shown in FIG. 6 each staple lies with its crown 90 extending along the respective conductor and both of the legs or pins 91 of the staple 9 engaging into first conductor 1 and both of the legs or pins 91 of the staple 10 engaging into second conductor 2.

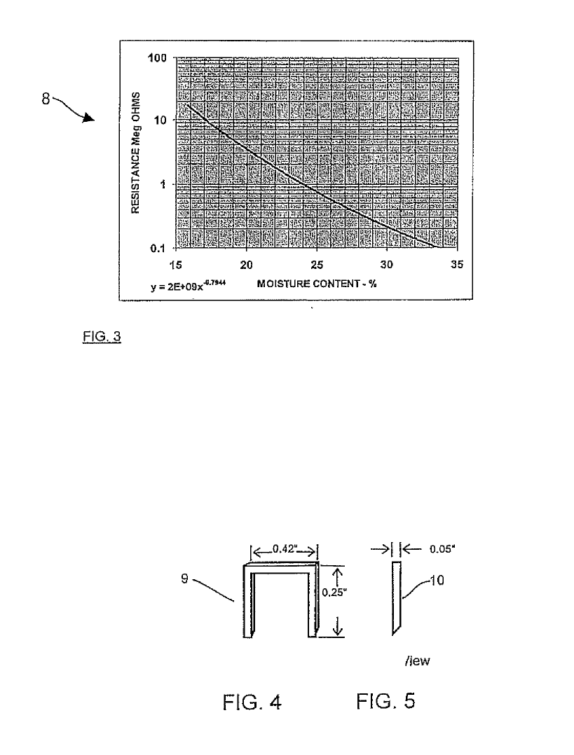

The probes form a moisture level measurement system. The electrical resistance between the probes, which are inserted parallel to one another in the two flat conductors, varies in proportion to the moisture content in the wood material. By carefully selecting the probe dimensions, distance apart and depth of insertion, the measured resistance can be used to calculate the percent moisture content in the wood according to the relationship illustrated in the graph of FIG. 3. This provides a noninvasive method to effectively and continuously monitor moisture levels. Unacceptably high moisture content levels, that would otherwise go undetected with a surface moisture detection method, are readily detected.

Typically up to ten pairs of moisture probes may be inserted on a single section of detection tape including, as shown in FIG. 6, a first pair 9, 10 of said up to ten pairs and a second pair 9A, 10A of said up to ten pairs. The parallel resistance of the probes can then be measured remotely by a pair of conductors that are spliced to the end of the detection tape.

The equivalent effective single probe resistance is then calculated by

R_{eff}=Rₘₑₐₛ./N (1)

### Where:

Rₘₑₐₛ. is the resultant measured resistance across the flat conductors

N is the number of probe pairs on a single tape run

From R_{eff}, the average moisture content can be calculated using:

M %=23.896 R_{eff}^{-0.1451} (2)

Where: M % is the average moisture content in the wood component

The moisture detection tape and probe system is then connected to a pair of insulated conductors 11 by means of insulation displacement connectors 12. The conductor pair is terminated on a pair of input terminals 13 of a sensor device 14 that measures the resistance of the moisture tape and probe combination.

While one embodiment of the present invention has been described in the foregoing, it is to be understood that other embodiments are possible within the scope of the appended claims.

1. A tape for application onto a surface of an absorbent material to be monitored for use in detecting moisture in the absorbent material, the tape comprising:
a substrate of dielectric, hydrophobic material with a bottom surface of the substrate arranged for application onto the surface of the absorbent material to be monitored;
first and second elongate, parallel, spaced apart conductors secured to a top surface of the substrate;
a protective layer of non-hygroscopic, water pervious, dielectric material secured to the top surface of the substrate and extending over the conductors; and
a mounting adhesive on a bottom surface of the substrate for attachment of the substrate to the surface of the absorbent material to be monitored;
the mounting adhesive being protected from adhering to other objects before being applied to the surface.

2. A tape according to claim 1 wherein the mounting adhesive is protected by a release sheet over the mounting adhesive.

3. A tape according to claim 1 wherein each of the conductors is a flat metal strip at least 6.5 mm wide.

4. A tape according to claim 1 wherein the conductors are spaced apart by a distance of at least 13 mm.

5. An apparatus comprising a tape according to claim 1 and further including a sensor unit for applying a voltage across the two conductors and monitoring currents passing between the conductors so as to detect changes in resistance between the conductors caused by moisture in the material.

6. A method of detecting moisture on a surface of an absorbent material, the method comprising:
providing a tape formed by a substrate of dielectric, hydrophobic material, a layer of a mounting adhesive on a bottom surface of the substrate and a first and a second spaced apart, elongate, parallel conductors mounted on a top surface of the substrate and extending therealong;
wherein each of the first and second conductors is a flat metal strip laid flat on the top surface of the substrate;
wherein the first and second conductors of the tape are covered along the tape by a protective layer of non-hygroscopic, water pervious, dielectric material secured to the top surface of the substrate and extending over the conductors;
attaching the tape by the adhesive on to a surface of the material so as to mount the two conductors on or adjacent the surface of the material;
applying a voltage across the first and second conductors; and
monitoring currents passing between the conductors so as to detect changes in resistance between the conductors caused by moisture in the material.

7. A method according to claim 6 wherein the absorbent material is a moisture permeable element of a building construction.
